(19) United States
(12) Patent Application Publication
(10) Pub. No.: US 2015/0219998 A1
(43) Pub. Date: Aug. 6, 2015

(54) LITHOGRAPHY APPARATUS, AND METHOD OF MANUFACTURING ARTICLE

(71) Applicant: CANON KABUSHIKI KAISHA, Tokyo (JP)

(72) Inventors: Atsushi Ito, LONG BEACH, CA (US); Nobushige Korenaga, Utsunomiya-shi (JP)

(21) Appl. No.: 14/590,199

(22) Filed: Jan. 6, 2015

(30) Foreign Application Priority Data
Jan. 31, 2014 (JP) 2014-017743

(51) Int. Cl. G03F 7/20

(52) U.S. Cl. CPC G03F 7/702

(57) ABSTRACT

The present invention provides a lithography apparatus including an optical system housing for an optical system which irradiates a substrate with a beam for forming a pattern, a reflecting member which is provided with the optical system housing and having a reflecting surface parallel to an optical axis of the optical system, and a measurement device configured to measure a rotation angle of the optical system housing by causing measurement light to be incident on each of at least three incident points which are not on the same straight line on the reflecting surface, wherein in the reflecting member a through-hole is formed in a region among the at least three incident points in a direction parallel to the optical axis, and is fixed to the optical system housing via a fixing member in the through-hole.

### BACKGROUND OF THE INVENTION

1. Field of the Invention

The present invention relates to a lithography apparatus, and a method of manufacturing an article.

2. Description of the Related Art

One of lithography apparatuses is a drawing apparatus which performs drawing on a substrate using charged particle beams. The drawing apparatus irradiates the substrate with charged particle beams emitted from a charged particle optical system and controls (deflects) the charged particle beams, thereby drawing (forming) an arbitrary pattern on the substrate (of the resist). The charged particle optical system is housed in an optical system barrel (optical system housing) and supported by a vacuum chamber.

High drawing positional accuracy is required for the pattern drawn on the substrate by the drawing apparatus. However, the drawing positional accuracy of the pattern decreases when, for example, a position fluctuation caused by the vibration of the optical system barrel of the charged particle optical system occurs. In a conventional exposure apparatus, as disclosed in Japanese Patent Laid-Open No. 2004-153092, so-called optical system barrel reference measurement which includes a measurement system for measuring the position of the optical system barrel housing a projection optical system and corrects an exposure position (pattern formation position) in real time based on a measurement result by the measurement system is performed. This optical system barrel reference measurement measures, using a plurality of interferometers, not only the position fluctuation of the optical system barrel in a translation direction but also the orientation fluctuation of the optical system barrel around each translation direction.

In the drawing apparatus whose optical system barrel housing the charged particle optical system is supported by the vacuum chamber, however, only a part of the optical system barrel can be arranged inside the vacuum chamber. This makes it impossible to provide a sufficient space for fixing a reflecting member (target) for optical system barrel measurement in a vertical direction. In other words, it is difficult to fix the reflecting member to the part of the optical system barrel (a small space in the vertical direction) arranged inside the vacuum chamber. Alternatively, if the size reduction of the reflecting member decreases the distance between the measurement axes of a pair of interferometers, the decrease in measurement accuracy and drawing positional accuracy (the positioning precision of a beam on the substrate) occurs.

### SUMMARY OF THE INVENTION

The present invention provides, for example, a lithography apparatus advantageous in positioning precision of a beam on a substrate.

According to one aspect of the present invention, there is provided a lithography apparatus which forms a pattern on a substrate, the apparatus including an optical system housing for an optical system which irradiates the substrate with a beam for forming the pattern, a reflecting member which is provided with the optical system housing and having a reflecting surface parallel to an optical axis of the optical system, and a measurement device configured to measure a rotation angle of the optical system housing by causing measurement light to be incident on each of at least three incident points which are not on the same straight line on the reflecting surface, wherein in the reflecting member a through-hole is formed in a region among the at least three incident points in a direction parallel to the optical axis, and is fixed to the optical system housing via a fixing member in the through-hole.

Further aspects of the present invention will become apparent from the following description of exemplary embodiments with reference to the attached drawings.

### BRIEF DESCRIPTION OF THE DRAWINGS

FIG. 1 is a schematic view showing the arrangement of a drawing apparatus as one aspect of the present invention.

FIG. 2 is a view showing an example of the arrangement relationship among an optical system barrel, an interferometer, and a reflecting member.

FIGS. 3A and 3B are views each showing an example of the reflecting member provided in the optical system barrel.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

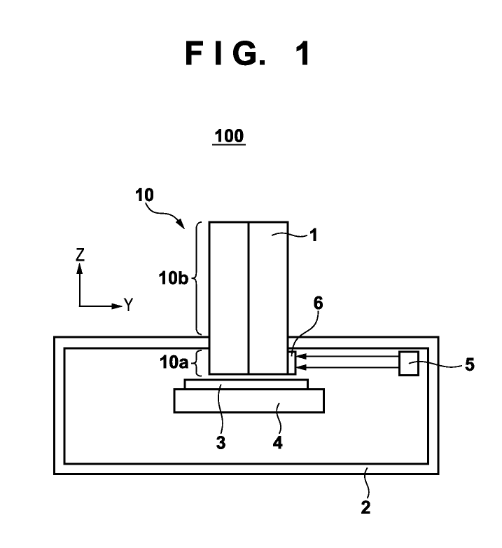

FIG. 1 is a schematic view showing the arrangement of a drawing apparatus 100 as one aspect of the present invention. The drawing apparatus 100 is a lithography apparatus which forms a pattern on a substrate and performs drawing on the substrate using charged particle beams. The drawing apparatus 100 includes a vacuum chamber 2, a substrate stage 4, an interferometer 5, a reflecting member 6, and an optical system barrel (optical system housing) 10.

The optical system barrel 10 houses an optical system which irradiates a substrate 3 with an energy beam for forming the pattern. In this embodiment, the optical system barrel 10 houses a plurality of charged particle optical systems 1 arrayed in a first direction (X-axis direction) and a second direction (Y-axis direction) which are perpendicular to a direction (Z-axis direction) parallel to an optical axis (that is, the optical system barrel houses the plurality of charged particle optical systems 1).

The vacuum chamber 2 houses a part 10a of the optical system barrel 10 and supports the optical system barrel 10. The optical system barrel 10, or more specifically, the part 10a of the optical system barrel 10 housed in the vacuum chamber 2 includes the reflecting member 6 having a reflecting surface parallel to the optical axis of the charged particle optical system 1. The interferometer 5 can measure the position and the rotation of the optical system barrel 10.

The substrate stage 4 is arranged under the optical system barrel 10, and can move in the X-axis and the Y-axis directions while holding the substrate 3. A measurement unit (not shown) such as an interferometer can measure the position of the substrate stage 4.

The drawing apparatus 100 also includes a control unit (not shown) including a CPU and a memory. An arbitrary pattern can be drawn on the substrate 3 by moving the substrate stage 4 within an X-Y plane while controlling (for example, selecting between the irradiation and the non-irradiation of the charged particle beams, and deflecting the charged particle beams), by the control unit, the charged particle beams from the optical system barrel 10 (charged particle optical system 1).

The drawing apparatus 100 has a constraint of arranging a high voltage power supply, the control unit, and the like in the atmosphere-side periphery of the optical system barrel 10, that is, in the periphery of a remaining part (the other part) 10b of the optical system barrel 10 which is not housed in the vacuum chamber 2. Therefore, a portion protruding inside the vacuum chamber 2 (housed in the vacuum chamber 2) is limited to the part 10a serving as the distal end. In other words, the part 10a of the optical system barrel 10 housed in the vacuum chamber 2 becomes smaller than the remaining part 10b of the optical system barrel 10 which is not housed in the vacuum chamber 2. The interferometer 5 is required to measure the position and the rotation of the optical system barrel 10 in such a limited space, that is, in the part 10a of the optical system barrel 10 housed in the vacuum chamber 2.

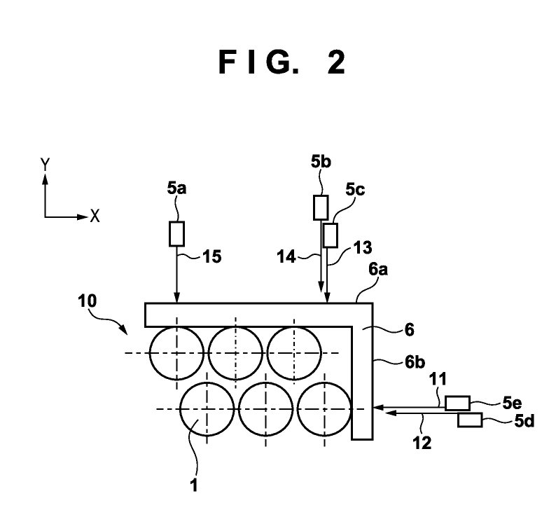

FIG. 2 is a view showing an example of the arrangement relationship among the optical system barrel 10 (charged particle optical systems 1), the interferometer 5, and the reflecting member 6. In FIG. 2, the optical system barrel 10 houses six charged particle optical systems 1. The six charged particle optical systems 1 are arranged to be spaced apart from each other by, for example, a 100-mm pitch in the Y-axis direction and a 50-mm pitch in the X-axis direction.

The moving stroke amount of the substrate stage 4 required to draw (expose) the entire surface of the substrate 3 is determined by the arrangement of the charged particle optical systems 1 housed in the optical system barrel 10. In this embodiment, for example, the substrate stage 4 needs to have a moving stroke of at least 50 mm in the X-axis direction and at least 400 mm in the Y-axis direction to draw the entire surface of the substrate 3 having a diameter of 300 mm. In other words, it is possible to draw the entire surface of the substrate 3 by drawing, using the respective charged particle optical systems 1 (the charged particle beams therefrom), on regions obtained by dividing the substrate 3 into strips every 50 mm in the X-axis direction.

As described above, in order to measure the position and the rotation of each of all the charged particle optical systems 1, that is, the optical system barrel 10 housing the charged particle optical systems 1, the optical system barrel 10 includes the reflecting member 6 which reflects measurement light from the interferometer 5. In this embodiment, the reflecting member 6 includes a reflecting surface 6a in the X-axis direction and a reflecting surface 6b in the Y-axis direction, and has an L shape in the X-Y plane. Furthermore, in this embodiment, the interferometer 5 includes five interferometers, namely, a first interferometer 5a, a second interferometer 5b, a third interferometer 5c, a fourth interferometer 5d, and a fifth interferometer 5e. Therefore, five axes, namely, a measurement axis 15 of the first interferometer 5a, a measurement axis 14 of the second interferometer 5b, a measurement axis 13 of the third interferometer 5c, a measurement axis 12 of the fourth interferometer 5d, and a measurement axis 11 of the fifth interferometer 5e are arranged for the reflecting member 6. The measurement axis 15 and the measurement axis 13 have the same position coordinate in the Z-axis direction but have different position coordinates in the X-axis direction. The measurement axis 14 and the measurement axis 13 have the same position coordinate in the X-axis direction but have different position coordinates in the Z-axis direction. The measurement axis 12 and the measurement axis 11 have the same position coordinate in the Y-axis direction but have different position coordinates in the Z-axis direction. This allows the interferometer 5, that is, the first interferometer 5a to the fifth interferometer 5e to measure the positions and orientations of five axes (a movement state of five degrees of freedom), namely, the positions in the X-axis direction and the Y-axis direction, and the rotations around the X-axis, the Y-axis, and the Z-axis of the optical system barrel 10.

The first interferometer 5a and the third interferometer 5c (the measurement axes 15 and 13) measure the rotation of the optical system barrel 10 around the Z-axis. The first interferometer 5a and the third interferometer 5c are spaced apart in the X-axis direction in which the position coordinates of all the charged particle optical systems 1 are different. In other words, the first interferometer 5a and the third interferometer 5c are spaced apart in the widthwise direction (X-axis direction) of the moving stroke (movable amount) of the substrate stage 4, which is perpendicular to the longitudinal direction (Y-axis direction) of the moving stroke of the substrate stage 4. This makes it possible to reduce (prevent) upsizing of the reflecting member 6 provided in the optical system barrel 10. Note that the length of the reflecting surface 6a of the reflecting member 6 corresponding to each of the first interferometer 5a and the third interferometer 5c suffices to cover at least the stroke of the substrate stage 4 in the X-axis direction, and to be 50 mm or more in this embodiment.

It is possible to increase the drawing positional accuracy by the charged particle beams by giving feedback on the position and the rotation of the optical system barrel 10 (the measurement result by the interferometer 5) measured by the first interferometer 5a to the fifth interferometer 5e to, for example, the control of the charged particle beams and the position control of the substrate stage 4.

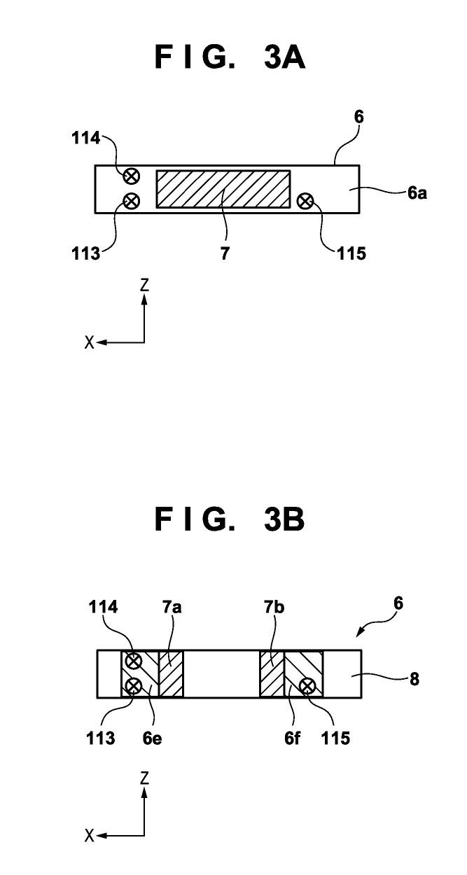

The reflecting member 6 provided in the optical system barrel 10 will now be described in detail. As shown in FIG. 3A, incident points 113, 114, and 115 are formed, by measurement light from each of the first interferometer 5a to the third interferometer 5c, on the reflecting surface 6a of the reflecting member 6. In other words, the interferometer 5 makes measurement light enter each of at least three incident points which are not in line with each other on the reflecting surface 6a (on the reflecting surface) of the reflecting member 6 and measures the rotation angle of the optical system barrel 10. In this embodiment, a fixing unit 7 for fixing the reflecting member 6 to the optical system barrel 10 is provided in a region defined by a polygon including all the incident points formed on the reflecting surface 6a (within a region among at least three incident points (113 to 115) in the direction parallel to the optical axis). More specifically, the fixing unit 7 is provided in a region, out of at least three incident points formed on the reflecting surface 6a, between two incident points 113 and 115 having the maximum interval in the X-axis direction and between two incident points 113 and 114 having the maximum interval in the Z-axis direction. For example, a through-hole which extends through the reflecting member 6 is formed in the fixing unit 7. A fixing member, for example, a fastening member such as a bolt or a rivet within the through-hole fixes (fastens) the reflecting member 6 to the optical system barrel 10. Note that fastening may be performed via a leaf spring or the like between the bolt and the reflecting member 6 to prevent the deformation of the reflecting surface 6a. In this case as well, the leaf spring and the bolt are arranged in the region (within the region) defined by the polygon.

By providing the fixing unit 7 on the reflecting surface 6a of the reflecting member 6 as described above, it becomes unnecessary to enlarge the reflecting member 6 in the Z-axis direction (optical-axis direction) to fix it to the optical system barrel 10. This makes it possible to keep a space of the part 10b of the optical system barrel 10 housed in the vacuum chamber 2 in the Z-axis direction (that is, a necessary portion for optical system barrel reference measurement) at a minimum. In other words, it is possible to provide (fix) the reflecting member 6 to the part 10b of the optical system barrel 10 housed in the vacuum chamber 2.

Furthermore, this embodiment can provide a larger space on the upper side of the vacuum chamber 2. This also brings about the effect of increasing the degree of freedom of arranging, for example, the high voltage power supply and the control unit as described above, and the degree of design freedom for the optical system barrel 10.

Also, as shown in FIG. 3B, the reflecting member 6 may be formed to cause a frame 8 to support the reflecting surfaces corresponding to the respective interferometers, for example, a reflecting surface 6e corresponding to the second interferometer 5b and the third interferometer 5c, and a reflecting surface 6f corresponding to the first interferometer 5a. In this case as well, by providing fixing units 7a and 7b in a region between the incident points 113 and 115, and between the incident points 113 and 114, it becomes possible to fix the reflecting member 6 to the optical system barrel 10 without enlarging it in the Z-axis direction (optical-axis direction).

As described above, the drawing apparatus 100 is advantageous in fixing the reflecting member 6 for measuring the rotation of the optical system barrel 10, and can fix the reflecting member 6 even if the space of the part 10b of the optical system barrel 10 housed in the vacuum chamber 2 in the Z-axis direction is small. This makes it possible, in the drawing apparatus 100, to perform optical system barrel reference measurement and increase the drawing positional accuracy by the charged particle beams. Therefore, the drawing apparatus 100 is suitable for manufacturing an article, for example, a microdevice such as a semiconductor device or an element having a microstructure. A method of manufacturing the article includes a step of forming a latent image pattern on a photoresist applied to a substrate using the drawing apparatus 100, and a step of processing (for example, developing) the substrate on which the latent image pattern has been formed in the preceding step (step of developing the substrate having undergone drawing). This manufacturing method can further include other known steps (oxidation, deposition, vapor deposition, doping, planarization, etching, resist peeling, dicing, bonding, packaging, and the like). The method of manufacturing the article according to this embodiment is advantageous in at least one of the performance, quality, productivity, and production cost of an article, as compared to a conventional method.

The present invention does not limit the lithography apparatus to the drawing apparatus, but can also be applied to the lithography apparatuses such as an exposure apparatus and an imprint apparatus. The exposure apparatus is a lithography apparatus which exposes the substrate via a reticle or a mask and a projection optical system using beams such as light and charged particles. On the other hand, the imprint apparatus is a lithography apparatus which molds an imprint material (such as a resin) on the substrate using a mold (die) and forms a pattern on the substrate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-017743, filed Jan. 31, 2014, which is hereby incorporated by reference herein in its entirety.

What is claimed is:

1. A lithography apparatus which forms a pattern on a substrate, the apparatus comprising:
an optical system housing for an optical system which irradiates the substrate with a beam for forming the pattern;
a reflecting member which is provided with the optical system housing and having a reflecting surface parallel to an optical axis of the optical system; and
a measurement device configured to measure a rotation angle of the optical system housing by causing measurement light to be incident on each of at least three incident points which are not on the same straight line on the reflecting surface,
wherein in the reflecting member a through-hole is formed in a region among the at least three incident points in a direction parallel to the optical axis, and is fixed to the optical system housing via a fixing member in the through-hole.

2. The apparatus according to claim 1, further comprising a chamber configured to house a part of the optical system housing and support the optical system housing,
wherein the reflecting member is provided with the part.

3. The apparatus according to claim 2, wherein the part is smaller than the other part of the optical system housing which is not housed in the chamber.

4. The apparatus according to claim 1, wherein in the reflecting member the through-hole is formed in a region between two incident points, of the at least three incident points, having the maximum interval in the direction parallel to the optical axis and between two incident points, of the at least three incident points, having the maximum interval in a direction orthogonal to the direction parallel to the optical axis.

5. The apparatus according to claim 1, wherein the fixing member includes a fastening member.

6. The apparatus according to claim 1, further comprising a stage configured to hold the substrate and be movable,
wherein the stage has a movable amount smaller in the direction parallel to the optical axis than in a direction orthogonal to the reflecting surface.

7. The apparatus according to claim 1, wherein the beam includes a charged particle beam.

8. The apparatus according to claim 1, wherein the optical system housing houses a plurality of the optical system.

9. A method of manufacturing an article, the method comprising steps of:
forming a pattern on a substrate using a lithography apparatus; and
processing the substrate on which the pattern has been formed,
wherein the lithography apparatus includes:
an optical system housing for an optical system which irradiates the substrate with a beam for forming the pattern;
a reflecting member which is provided with the optical system housing and having a reflecting surface parallel to an optical axis of the optical system; and
a measurement device configured to measure a rotation angle of the optical system housing by causing measurement light to be incident on each of at least three incident points which are not on the same straight line on the reflecting surface,
wherein in the reflecting member a through-hole is formed in a region among the at least three incident points in a direction parallel to the optical axis, and is fixed to the optical system housing via a fixing member in the through-hole.
